(19) United States
(12) Patent Application Publication
(10) Pub. No.: US 2024/0331981 A1
(43) Pub. Date: Oct. 3, 2024

(54) SHOWERHEAD, SUBSTRATE PROCESSING APPARATUS INCLUDING THE SAME, AND SEMICONDUCTOR FABRICATION METHOD USING THE SAME

(71) Applicant: SAMSUNG ELECTRONICS CO., LTD., Suwon-si (KR)

(72) Inventor: HYUNGSIK KO, Suwon-si (KR)

(21) Appl. No.: 18/541,356

(22) Filed: Dec. 15, 2023

(30) Foreign Application Priority Data
Apr. 3, 2023 (KR) 10-2023-0043411

(51) Int. Cl. H01J 37/32

(52) U.S. Cl. CPC H01J 37/32449; H01J 2237/334

(57) ABSTRACT

The present disclosure relates to showerheads, substrate processing apparatuses, and semiconductor fabrication methods. One example showerhead comprises an inner plate, and an outer plate combined with the inner plate and surrounding the inner plate. The inner plate includes a disk-shaped central member that comprises a gas hole extending in a first direction, and a ring-shaped first coupling member outside the central member and surrounding the central member. The outer plate includes an outer ring body and a ring-shaped second coupling member inside the outer ring body. A bottom surface of the first coupling member is in contact with a top surface of the second coupling member. A first angle between the first direction and an outer surface of the first coupling member is different from a second angle between the first direction and an inner surface of the outer ring body.

### CROSS-REFERENCE TO RELATED APPLICATION

This application claims priority to Korean Patent Application No. 10-2023-0043411, filed on Apr. 3, 2023, in the Korean Intellectual Property Office, the disclosure of which is hereby incorporated by reference in its entirety.

### BACKGROUND

The present disclosure relate to a showerhead, a substrate processing apparatus including the same, and a semiconductor fabrication method using the same, and more particularly, to a showerhead capable of increasing a lifetime thereof, a substrate processing apparatus including the same, and a semiconductor fabrication method using the same.

A semiconductor device may be fabricated by using various processes. For example, a semiconductor device may be manufactured by allowing a silicon wafer to undergo a photolithography process, an etching process, a deposition process, and so forth. Various fluids may be used in such processes. For example, plasma may be used in an etching process and/or a deposition process. The plasma may be generated from gas. A showerhead may be used to supply the gas to a substrate.

### SUMMARY

The present disclosure relates to a showerhead capable of increasing a lifetime thereof, a substrate processing apparatus including the same, and a semiconductor fabrication method using the same.

The present disclosure also relates to a showerhead capable of being promptly and accurately assembled, a substrate processing apparatus including the same, and a semiconductor fabrication method using the same.

The present disclosure also relates to a showerhead capable of increasing a substrate etching yield, a substrate processing apparatus including the same, and a semiconductor fabrication method using the same.

The object of the present disclosure is not limited to the mentioned above, and other objects which have not been mentioned above will be clearly understood to those skilled in the art from the following description.

In some implementations, a showerhead may comprise: an inner plate; and an outer plate combined with the inner plate, the outer plate surrounding the inner plate. The inner plate may include: a disk-shaped central member that provides a gas hole extending in a first direction; and a ring-shaped first coupling member outside the central member, the first coupling member surrounding the central member. The outer plate may include: an outer ring body; and a ring-shaped second coupling member inside the outer ring body. A bottom surface of the first coupling member may be in contact with a top surface of the second coupling member. A first angle between the first direction and an outer surface of the first coupling member may be different from a second angle between the first direction and an inner surface of the outer ring body.

In some implementations, a substrate processing apparatus may comprise: a process chamber that provides a process space; a stage in the process chamber; and a showerhead upwardly spaced apart from the stage. The showerhead may include: an inner plate; and an outer plate combined with the inner plate, the outer plate surrounding the inner plate. The inner plate may include: a disk-shaped central member that provides a plurality of gas holes extending in a first direction; and a ring-shaped first coupling member outside the central member, the first coupling member surrounding the central member. A bottom surface of the first coupling member may be at a level higher than a level of a bottom surface of the central member. A first distance between an edge gas hole and an outer surface of the central member may be in a range of about 2.5 mm to about 8 mm. The edge gas hole may be one among the plurality of gas holes that is most adjacent to the first coupling member.

In some implementations, a semiconductor fabrication method may comprise: loading a substrate into a substrate processing apparatus; supplying a process gas into the substrate processing apparatus; and applying a radio-frequency (RF) power to a plasma electrode. The substrate processing apparatus may include: a stage that supports the substrate; and a showerhead upwardly spaced apart from the stage. The showerhead may include: an inner plate; and an outer plate combined with the inner plate. The outer plate may surround the inner plate. The outer plate may include: an outer ring body; and a ring-shaped second coupling member inside the outer ring body. The inner plate may include: a disk-shaped central member that provides a gas hole extending in a first direction; and a first coupling member on the second coupling member. The first coupling member may surround the central member. An upper end of an outer surface of the first coupling member may be in contact with an upper end of an inner surface of the outer ring body. A gap may be between the outer surface of the first coupling member and the inner surface of the outer ring body.

Details of other example implementations are included in the description and drawings.

### BRIEF DESCRIPTION OF DRAWINGS

FIG. 1 illustrates a cross-sectional view showing an example of a substrate processing apparatus.

FIG. 2 illustrates an example enlarged cross-sectional view showing section X of FIG. 1.

FIG. 3 illustrates a perspective view showing an example of a showerhead.

FIG. 4 illustrates an exploded perspective view showing an example of a showerhead.

FIG. 5 illustrates an example enlarged bottom view showing section Y of FIG. 1.

FIG. 6 illustrates a cross-sectional view partially showing an example of a showerhead.

FIG. 7 illustrates a cross-sectional view partially showing an example of an inner plate.

FIG. 8 illustrates a cross-sectional view partially showing an example of an outer plate.

FIG. 9 illustrates a plan view showing an example of an inner plate.

FIG. 10 illustrates an example enlarged plan view showing section Z of FIG. 9.

FIG. 11 illustrates a flow chart showing an example of a semiconductor fabrication method.

FIGS. 12 to 16 illustrate example cross-sectional views showing the semiconductor fabrication method of FIG. 11.

FIG. 17 illustrates a cross-sectional view partially showing another example of a showerhead.

### DETAILED DESCRIPTION

The following will now describe some implementations of the present disclosure with reference to the accompanying drawings. Like reference numerals may indicate like components throughout the description.

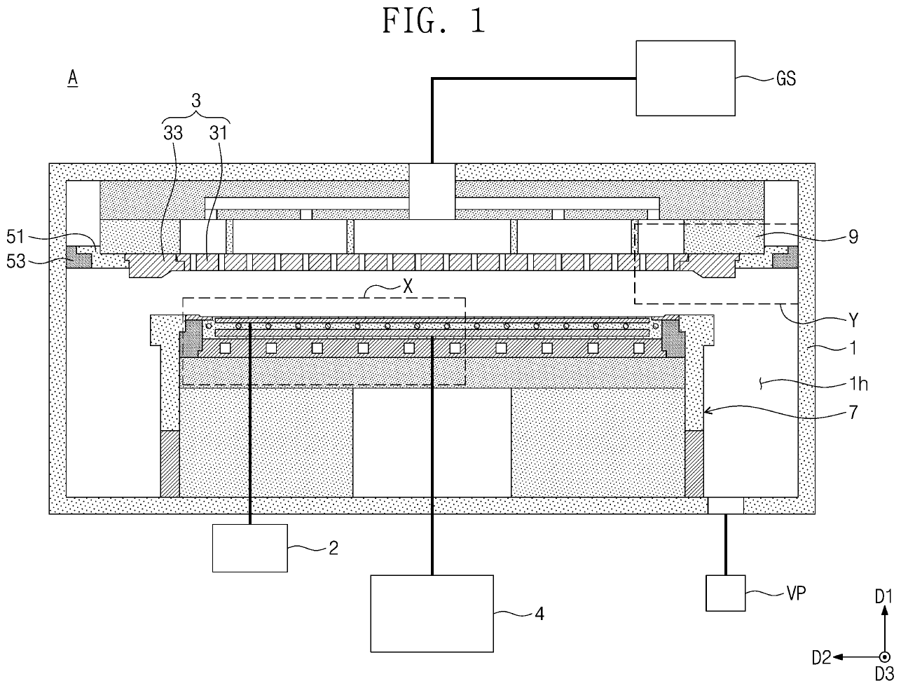

FIG. 1 illustrates a cross-sectional view showing an example of a substrate processing apparatus.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called a vertical direction. Each of the second direction D2 and the third direction D3 may be called a horizontal direction.

Referring to FIG. 1, a substrate processing apparatus A is provided. The substrate processing apparatus A may be configured to allow a substrate to undergo an etching process and/or a deposition process. A term “substrate” used in this description may denote a silicon (Si) wafer, but the present disclosure is not limited thereto. The substrate processing apparatus A may use plasma to treat a substrate. The substrate processing apparatus A may generate plasma in various ways. For example, the substrate processing apparatus A may be a capacitively coupled plasma (CCP) apparatus and/or an inductively coupled plasma (ICP) apparatus. For convenience, the following will illustrate and discuss a CCP type substrate processing apparatus. The substrate processing apparatus A may include a process chamber 1, a stage 7, a showerhead 3, an outer ring 51, a heating liner ring 53, a direct-current (DC) power generator 2, a radio-frequency (RF) power generator 4, a vacuum pump (VP), and a gas supply device (GS).

The process chamber 1 may provide a process space 1h. A substrate process may be performed in the process space 1h. The process space 1h may be isolated from an external space. During a substrate process, the process space 1h may be in a substantial vacuum state. The process chamber 1 may have a cylindrical shape, but the present disclosure is not limited thereto.

The stage 7 may be positioned in the process chamber 1. For example, the stage 7 may be positioned in the process space 1h. The stage 7 may support and/or fix a substrate. A substrate process may be performed in a state where a substrate is placed on the stage 7. The stage 7 will be further discussed in detail below.

The showerhead 3 may be positioned in the process chamber 1. For example, the showerhead 3 may be positioned in the process space 1h. The showerhead 3 may be disposed upwardly spaced apart from the stage 7. A gas supplied from the GS may be uniformly sprayed through the showerhead 3 into the process space 1h. The showerhead 3 may include an inner plate 31 and an outer plate 33. The inner plate 31 and the outer plate 33 may be separable from each other. For example, the inner plate 31 and the outer plate 33 may be separate components from each other. The showerhead 3 will be further discussed in detail below.

The outer ring 51 may surround the showerhead 3. For example, outside the showerhead 3 when viewed in plan, the outer ring 51 may surround the showerhead 3. The outer ring 51 may be in contact with the showerhead 3. The outer ring 51 may include quartz. The outer ring 51 will be further discussed in detail below.

The heating liner ring 53 may surround the outer ring 51. For example, outside the outer ring 51 when viewed in plan, the heating liner ring 53 may surround the outer ring 51. The heating liner ring 53 may support the outer ring 51. The heating liner ring 53 may include a different material from that of the outer ring 51. For example, the heating liner ring 53 may include aluminum (Al) and yttrium (Y₂O₃). In more detail, yttrium (Y₂O₃) may be coated on aluminum (Al) to form the heating liner ring 53. The heating liner ring 53 will be further discussed in detail below.

The DC power generator 2 may apply a DC power to the stage 7. The DC power applied from the DC power generator 2 may rigidly place a substrate on a certain position on the stage 7.

The RF power generator 4 may supply a RF power to the stage 7. It may thus be possible to control plasma in the process space 1h. A detailed description thereof will be further discussed below.

The VP may be connected to the process space 1h. The VP may apply a vacuum pressure to the process space 1h during a substrate process.

The GS may supply the process space 1h with gas. The GS may include a gas tank, a compressor, and a valve. The plasma may be generated from a portion of gas supplied from the GS to the process space 1h.

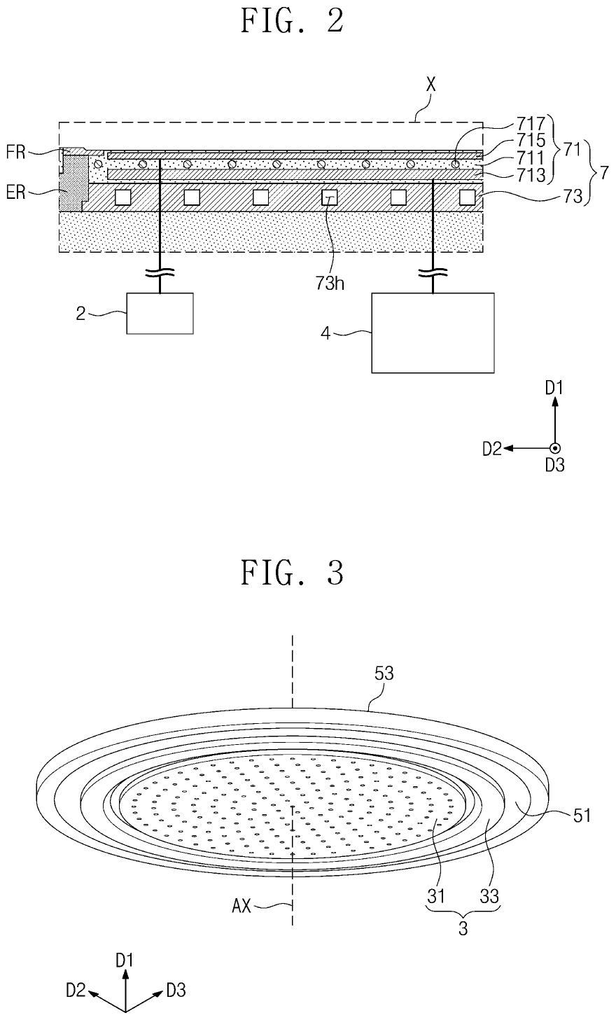

FIG. 2 illustrates an example enlarged cross-sectional view showing section X of FIG. 1.

Referring to FIG. 2, the stage 7 may include a chuck 71 and a cooling plate 73.

A substrate may be disposed on the chuck 71. The chuck 71 may fix a substrate on a certain position thereof. The chuck 71 may include a chuck body 711, a plasma electrode 713, a chuck electrode 715, and a heater 717.

The chuck body 711 may have a cylindrical shape. The chuck body 711 may include a ceramic, but the present disclosure is not limited thereto. A substrate may be disposed on a top surface of the chuck body 711. The chuck body 711 may be surrounded by a focus ring FR and/or an edge ring ER.

The plasma electrode 713 may be positioned in the chuck body 711. The plasma electrode 713 may include aluminum (Al). The plasma electrode 713 may have a disk shape, but the present disclosure is not limited thereto. A RF power may be applied to the plasma electrode 713. For example, the RF power generator 4 may apply a RF power to the plasma electrode 713. The RF power applied to the plasma electrode 713 may control plasma in the process space (see 1h of FIG. 1).

The chuck electrode 715 may be positioned in the chuck body 711. The chuck electrode 715 may be positioned higher than the plasma electrode 713. A DC power may be applied to the chuck electrode 715. For example, the DC power generator 2 may apply a DC power to the chuck electrode 715. The DC power applied to the chuck electrode 715 may rigidly place a substrate on a certain position on the chuck body 711. The chuck electrode 715 may include aluminum (Al), but the present disclosure is not limited thereto.

The heater 717 may be positioned in the chuck body 711. The heater 717 may be positioned between the chuck electrode 715 and the plasma electrode 713. The heater 717 may include a hot wire. For example, the heater 717 may include a concentrically circular shaped hot wire. The heater 717 may radiate heat to a surrounding environment. Therefore, the chuck body 711 may have an increased temperature.

The cooling plate 73 may be positioned below the chuck 71. For example, the chuck 71 may be positioned on the cooling plate 73. The cooling plate 73 may provide a cooling hole 73h. Cooling water may flow through the cooling hole 73h. The cooling water in the cooling hole 73h may absorb heat from the cooling plate 73.

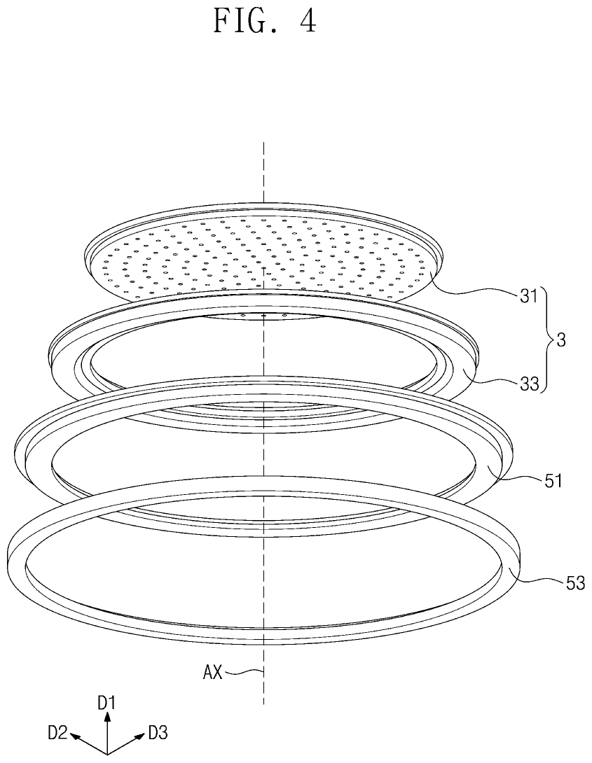

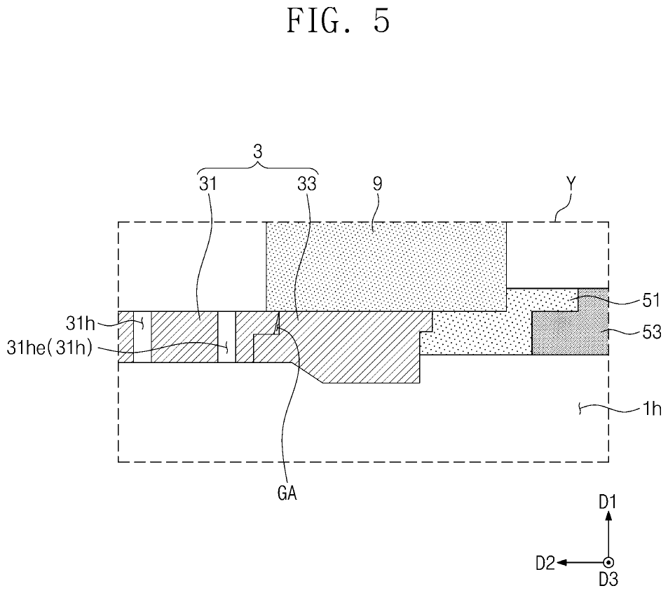

FIG. 3 illustrates a perspective view showing an example of a showerhead. FIG. 4 illustrates an exploded perspective view showing an example of a showerhead. FIG. 5 illustrates an example enlarged bottom view showing section Y of FIG. 1.

Referring to FIGS. 3 to 5, the inner plate 31 may have an axis AX that extend in the first direction D1. The inner plate 31 may provide a gas hole 31h. The gas hole 31h may penetrate in the first direction D1 through the inner plate 31. The gas hole 31h may be provided in plural. The plurality of gas holes 31h may be spaced apart from each other in a horizontal direction. Among the plurality of gas holes 31h, one most adjacent to the outer plate 33 may be called an edge gas hole 31he. A detailed description thereof will be further discussed below. A single gas hole 31h will be discussed below in the interest of convenience. The inner plate 31 may include silicon (Si). Silicon (Si) on a surface of the inner plate 31 may have a crystallographic direction of <111>. The present disclosure, however, is not limited thereto.

The outer plate 33 may be combined with the inner plate 31 so as to surround the inner plate 31. The outer plate 33 may have a ring shape around the axis AX. The outer plate 33 will be further discussed in detail below.

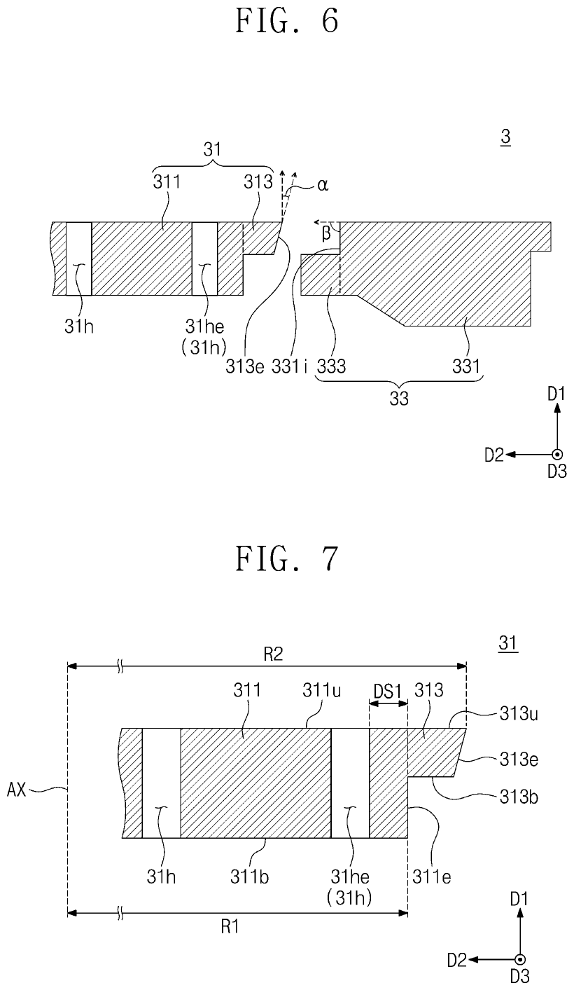

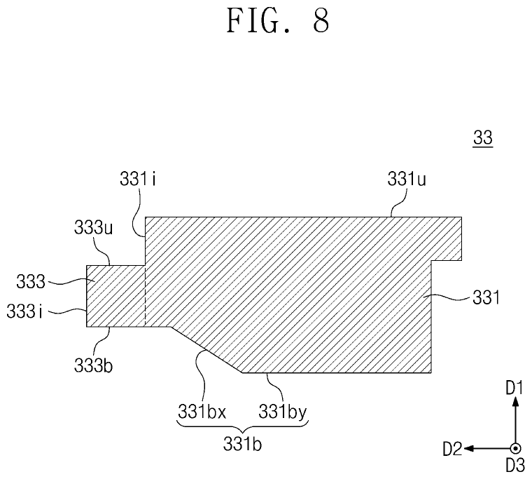

FIG. 6 illustrates a cross-sectional view partially showing an example of a showerhead. FIG. 7 illustrates a cross-sectional view partially showing an example of an inner plate. FIG. 8 illustrates a cross-sectional view partially showing an example of an outer plate.

Referring to FIG. 6, the inner plate 31 may include a central member 311 and a first coupling member 313.

The central member 311 may have a disk shape. The gas hole 31h may be provided in the central member 311. For example, the gas hole 31h may penetrate in the first direction D1 through the central member 311. The gas hole 31h may connect a top surface 311u of the central member 311 to a bottom surface 311b of the central member 311. A first radius R1 may be defined to refer to a radius of an outer surface 311e of the central member 311. The first radius R1 may indicate a horizontal distance between the axis AX and the outer surface 311e of the central member 311. The first radius R1 may range, for example, about 155 mm to about 157.5 mm. Therefore, the outer surface 311e of the central member 311 may have a diameter of about 310 mm to about 315 mm.

The first coupling member 313 may be positioned outside the central member 311. The first coupling member 313 may surround the central member 311. The first coupling member 313 may have a ring shape. The first coupling member 313 and the central member 311 may be formed into a single unitary body, but the present disclosure is not limited thereto. A bottom surface 313b of the first coupling member 313 may be located at a level higher than that of the bottom surface 311b of the central member 311. A top surface 313u of the first coupling member 313 may be located at a level substantially the same as that of the top surface 311u of the central member 311. For example, the top surface 313u of the first coupling member 313 and the top surface 311u of the central member 311 may be positioned on the same plane. A first angle α may be made between the first direction D1 and an outer surface 313e of the first coupling member 313. The first angle α may be an acute angle. For example, the first angle α may range from about 0.5° to about 6°. A second radius R2 may be defined to refer to a radius of the outer surface 313e of the first coupling member 313. The second radius R2 may indicate a horizontal distance between the axis AX and the outer surface 313e of the first coupling member 313. The second radius R2 may range, for example, about 161.5 mm to about 163 mm. Therefore, the outer surface 313e of the first coupling member 313 may have a diameter of about 323 mm to about 326 mm.

A first distance DS1 may be defined to refer to a distance between the edge gas hole 31he and the outer surface 311e of the central member 311. The first distance DS1 may range, for example, from about 2.5 mm to about 8 mm. A detailed description thereof will be further discussed below.

The outer plate 33 may include an outer ring body 331 and a second coupling member 333.

The outer ring body 331 may have a ring shape. A second angle 90°-β may be made between the first direction D1 and an inner surface 331i of the outer ring body 331. The second angle 90°-β may be less than the first angle α. For example, the first angle α may be greater than the second angle 90°-β. The second angle 90°-β may be, for example, about 0°. For example, the inner surface 331i of the outer ring body 331 may be parallel to the first direction D1. A top surface 331u of the outer ring body 331 may be located at a level substantially the same as that of the top surface 313u of the first coupling member 313. For example, the top surface 313u of the first coupling member 313 and the top surface 331u of the outer ring body 331 may be positioned on the same plane. A bottom surface 331b of the outer ring body 331 may include a first bottom surface 331bx and a second bottom surface 331by. An acute angle may be made between the first bottom surface 331bx and the first direction D1. The second bottom surface 331by may be perpendicular to the first direction D1. The present disclosure, however, is not limited thereto.

The second coupling member 333 may be positioned inside the outer ring body 331. The second coupling member 333 may have a ring shape. The second coupling member 333 and the outer ring body 331 may be formed into a single unitary body, but the present disclosure is not limited thereto. A top surface 333u of the second coupling member 333 may be located at a level lower than that of the top surface 331u of the outer ring body 331. A bottom surface 333b of the second coupling member 333 may be connected to the first bottom surface 331bx of the outer ring body 331. The inner surface 333i of the second coupling member 333 may be parallel to the first direction D1.

Referring to FIGS. 5 and 6, the first coupling member 313 may be positioned on the second coupling member 333. For example, the bottom surface 313b of the first coupling member 313 may be in contact with the top surface 333u of the second coupling member 333. A portion of the outer surface 313e of the first coupling member 313 may be in contact with a portion of the inner surface 331i of the outer ring body 331. For example, an upper end of the outer surface 313e of the first coupling member 313 may be in contact with an upper end of the inner surface 331i of the outer ring body 331. The upper end of the outer surface 313e of the first coupling member 313 may be in line contact with the upper end of the inner surface 331i of the outer ring body 331. Therefore, a gap may be formed between the outer surface 313e of the first coupling member 313 and the inner surface 331i of the outer ring body 331.

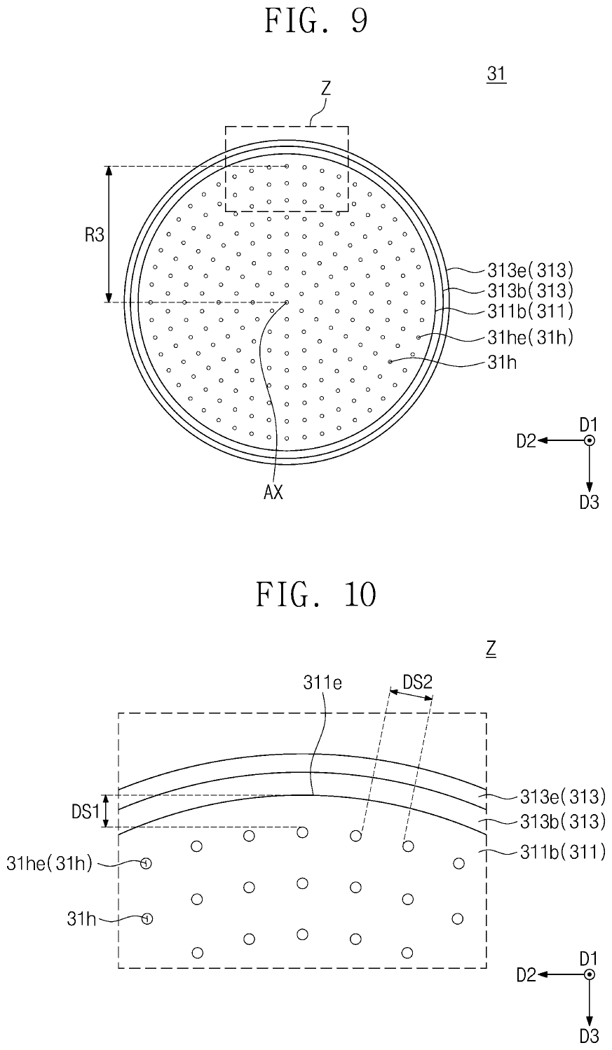

FIG. 9 illustrates a plan view showing an example of an inner plate. FIG. 10 illustrates an example enlarged plan view showing section Z of FIG. 9.

Referring to FIG. 9, a third radius R3 may be defined to refer to a distance between the edge gas hole 31he and the axis AX. For example, the third radius R3 may be a distance in a radius direction between the axis AX and the edge gas hole 31he. The third radius R3 may range, for example, about 152 mm to about 154 mm.

Referring to FIG. 10, the edge gas hole 31he may be provided in plural. The plurality of edge gas holes 31he may be spaced apart from each other in a circumferential direction. A second distance DS2 may be defined to refer to a distance between two neighboring ones among the plurality of edge gas holes 31he. The first distance DS1 may be greater than half the second distance DS2. Therefore, the outer surface 311e of the central member 311 may be prevented from being etched and fractured due to contact with the edge gas hole 31he.

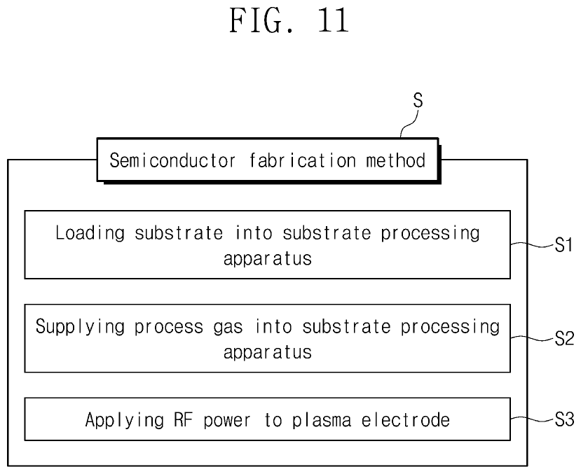

FIG. 11 illustrates a flow chart showing an example of a semiconductor fabrication method.

Referring to FIG. 11, a semiconductor fabrication method S may be provided. The semiconductor fabrication method S may be a way of manufacturing a semiconductor device by using the substrate processing apparatus (see A of FIG. 1) discussed with reference to FIGS. 1 to 10. The semiconductor fabrication method S may include loading a substrate into a substrate processing apparatus (S1), supplying a process gas into the substrate processing apparatus (S2), and applying a RF power to a plasma electrode (S3).

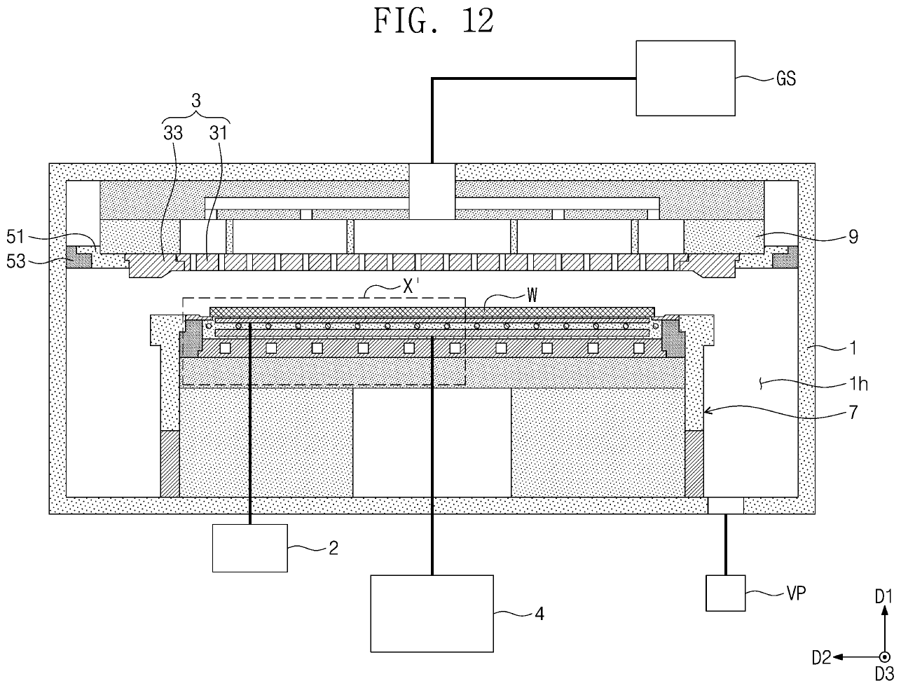

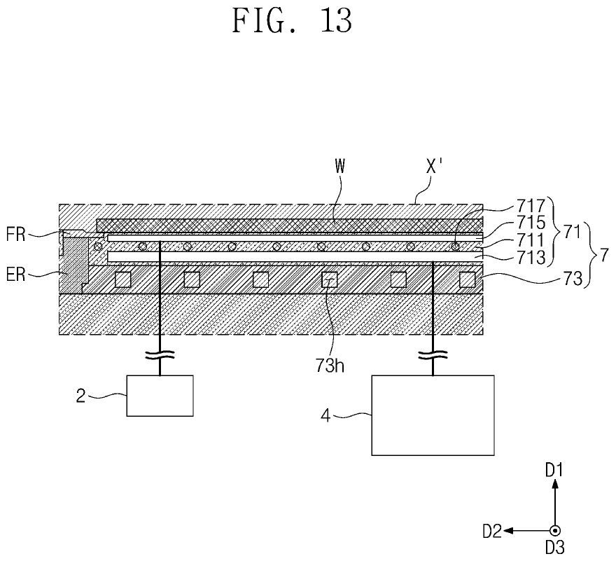

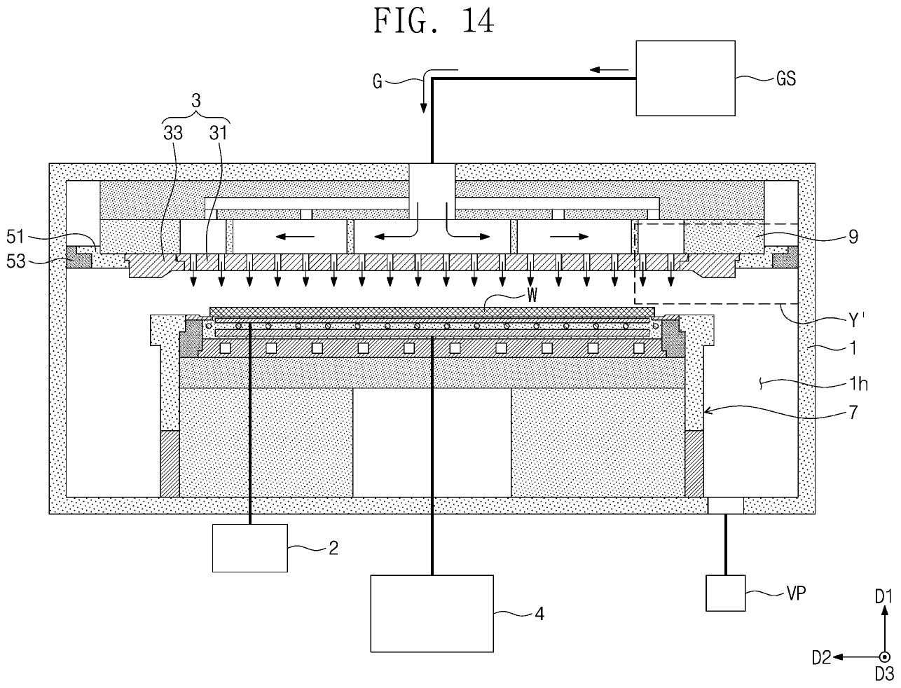

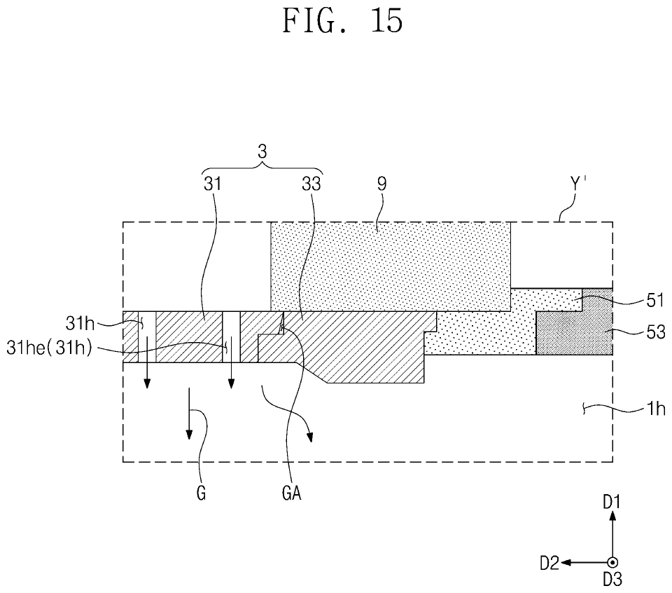

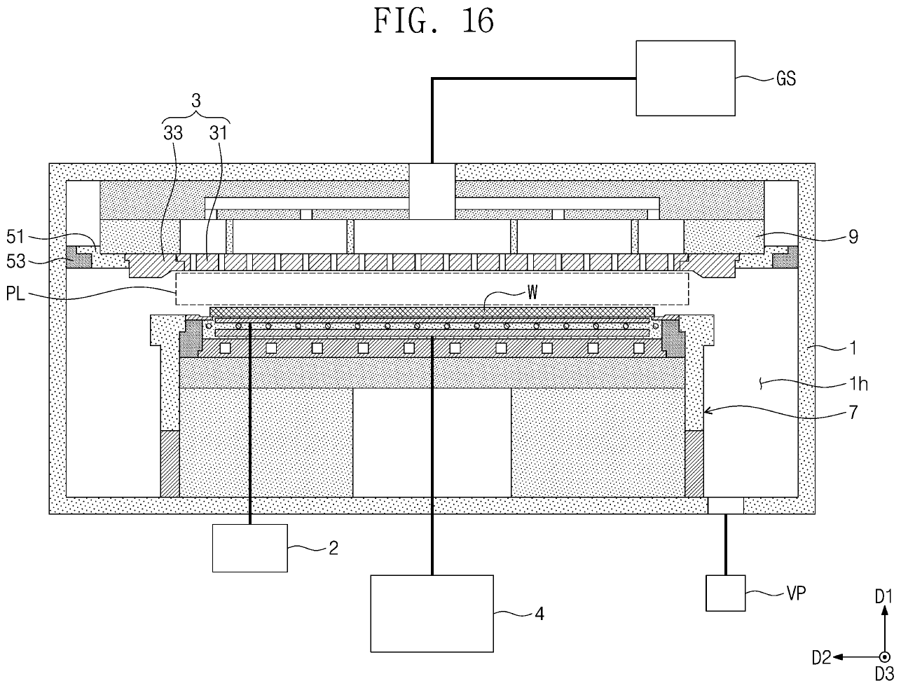

The semiconductor fabrication method S will be discussed below with reference to FIGS. 12 to 16.

FIGS. 12 to 16 illustrate example cross-sectional views showing the semiconductor fabrication method of FIG. 11.

Referring to FIGS. 11, 12, and 13, a substrate loading step S1 may include placing a substrate W on the stage 7. The substrate W may be fixed to the stage 7. For example, a direct-current (DC) power applied to the chuck electrode 715 may rigidly place the substrate W onto the stage 7.

Referring to FIGS. 11, 14, and 15, the gas supply step S2 may include allowing the GS to supply a process gas G to the process space 1h. The process gas G may be uniformly distributed through the showerhead 3.

Referring to FIGS. 11, 13, and 16, the power apply step S3 may include allowing the RF power generator 4 to apply a radio-frequency (RF) power to the plasma electrode 713. Therefore, an electric field and/or a magnetic field may be produced in the process space 1h. A plasma PL may be generated from at least a portion of the process gas (see G of FIG. 15) supplied to the process space 1h. The plasma PL may treat the substrate W.

According to a showerhead, a substrate processing apparatus including the same, and a semiconductor fabrication method using the same in accordance with some implementations of the present disclosure, when an inner plate and an outer plate are combined with each other, an inclined outer surface of a first coupling member may facilitate coupling the inner plate and the outer plate. For example, an upper end of the outer surface of the first coupling member may be in line contact with an upper end of an inner surface of an outer ring body, and thus the inner plate and the outer plate may be accurately assembled. Therefore, the inner plate and the outer plate may be accurately assembled even without additional tools. In addition, an assembly process may be possibly performed at high speeds.

According to a showerhead, a substrate processing apparatus including the same, and a semiconductor fabrication method using the same in accordance with some implementations of the present disclosure, a distance between an edge gas hole and an outer surface of a central member may be secured to a certain value or higher. For example, the distance between an edge gas hole and the outer surface of a central member may be greater than half that between two neighboring edge gas holes. It may thus be possible to prevent a gas hole from being deformed due to contact with the edge gas hole resulting from etching of the outer surface of the central member. Therefore, the showerhead may have an increased lifetime. In addition, the occurrence of particles may be suppressed to increase a substrate etching yield.

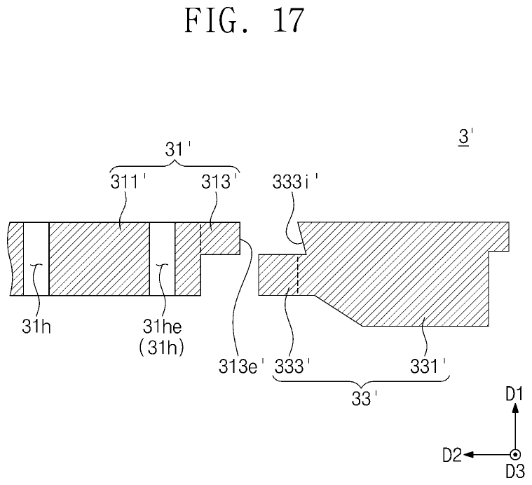

FIG. 17 illustrates a cross-sectional view partially showing another example of a showerhead.

The following will omit a description substantially the same as or similar to that discussed with reference to FIGS. 1 to 16.

Referring to FIG. 17, a showerhead 3′ may include an inner plate 31′ and an outer plate 33′. The inner plate 31′ may include a central member 311′ and a first coupling member 313′. The outer plate 33′ may include an outer ring body 331′ and a second coupling member 333′. An outer surface 313e′ of the first coupling member 313′ may be parallel to the first direction D1. An acute angle may be made between the first direction D1 and an inner surface 331i′ of the outer ring body 331′.

According to a showerhead, a substrate processing apparatus including the same, and a semiconductor fabrication method using the same in accordance with the present disclosure, the showerhead may have an increased lifetime.

According to a showerhead, a substrate processing apparatus including the same, and a semiconductor fabrication method using the same in accordance with the present disclosure, the showerhead may be accurately assembled at high speeds.

According to a substrate processing apparatus including the same, and a semiconductor fabrication method using the same in accordance with the present disclosure, a substrate etching yield may increase.

Effects of the present disclosure is not limited to the mentioned above, other effects which have not been mentioned above will be clearly understood to those skilled in the art from the following description.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although the concepts disclosed herein have been described in connection with some implementations of the present disclosure illustrated in the accompanying drawings, it will be understood to those skilled in the art that various changes and modifications may be made without departing from the technical spirit and essential feature of the concepts. It therefore will be understood that the embodiments described above are just illustrative but not limitative in all aspects.

What is claimed is:

1. A substrate processing apparatus, comprising a showerhead,
wherein the showerhead includes:
an inner plate; and
an outer plate combined with the inner plate, the outer plate surrounding the inner plate,
wherein the inner plate includes:
a disk-shaped central member that comprises a gas hole extending in a first direction; and
a ring-shaped first coupling member outside the central member, the first coupling member surrounding the central member,
wherein the outer plate includes:
an outer ring body; and
a ring-shaped second coupling member inside the outer ring body,
wherein a bottom surface of the first coupling member is in contact with a top surface of the second coupling member, and
wherein a first angle between the first direction and an outer surface of the first coupling member is different from a second angle between the first direction and an inner surface of the outer ring body.

2. The s substrate processing apparatus of claim 1, wherein the first angle is greater than the second angle to form a gap between the outer surface of the first coupling member and the inner surface of the outer ring body.

3. The substrate processing apparatus of claim 2, wherein the first angle is in a range of about 0.5° to about 6°, and the second angle is about 0°.

4. The substrate processing apparatus of claim 1, wherein the disk-shaped central member comprises a plurality of gas holes, and a first distance between an edge gas hole and an outer surface of the central member is in a range of about 2.5 mm to about 8 mm, the edge gas hole being one among the plurality of gas holes that are closest to the second coupling member.

5. The substrate processing apparatus processing apparatus of claim 4, wherein a distance in a radius direction between the edge gas hole and an axis of the central member is in a range of about 152 mm to about 154 mm, the axis extending in the first direction.

6. The substrate processing apparatus of claim 1, wherein the disk-shaped central member comprises a plurality of gas holes,
wherein the plurality of gas holes include a plurality of edge gas holes closest to the second coupling member,
wherein the plurality of edge gas holes are spaced apart from each other in a circumferential direction, and
wherein a first distance between an outer surface of the central member and each of the plurality of edge gas holes is greater than half a distance between two neighboring ones among the plurality of edge gas holes.

7. The substrate processing apparatus of claim 1, wherein an upper end of the outer surface of the first coupling member is in contact with an upper end of the inner surface of the outer ring body.

8. The substrate processing apparatus of claim 1, wherein a top surface of the central member, a top surface of the first coupling member, and a top surface of the outer ring body are on a same plane.

9. The substrate processing apparatus of claim 8, wherein
a bottom surface of the first coupling member is at a level higher than a level of a bottom surface of the central member, and
a bottom surface of the second coupling member is at a same level as the bottom surface of the central member.

10. The substrate processing apparatus of claim 9, wherein a hole is not on each of the bottom surface of the first coupling member and the top surface of the second coupling member.

11. A substrate processing apparatus, comprising:
a process chamber that comprises a process space;
a stage in the process chamber; and
a showerhead upwardly spaced apart from the stage,
wherein the showerhead includes:
an inner plate; and
an outer plate combined with the inner plate, the outer plate surrounding the inner plate,
wherein the inner plate includes:
a disk-shaped central member that comprises a plurality of gas holes extending in a first direction; and
a ring-shaped first coupling member outside the central member, the first coupling member surrounding the central member,
wherein a bottom surface of the first coupling member is at a level higher than a level of a bottom surface of the central member, and
wherein a first distance between an edge gas hole and an outer surface of the central member is in a range of about 2.5 mm to about 8 mm, the edge gas hole being one among the plurality of gas holes that are closest to the first coupling member.

12. The substrate processing apparatus of claim 11, wherein the outer surface of the central member has a diameter of about 310 mm to about 315 mm, and an outer surface of the first coupling member has a diameter of about 323 mm to about 326 mm.

13. The substrate processing apparatus of claim 11, wherein the outer plate includes:
an outer ring body; and
a ring-shaped second coupling member inside the outer ring body, wherein the bottom surface of the first coupling member is on a top surface of the second coupling member.

14. The substrate processing apparatus of claim 13, wherein a first angle between the first direction and an outer surface of the first coupling member is different from a second angle between the first direction and an inner surface of the outer ring body.

15. The substrate processing apparatus of claim 14, wherein an upper end of the outer surface of the first coupling member is in contact with an upper end of the inner surface of the outer ring body to form a gap between the outer surface of the first coupling member and the inner surface of the outer ring body.

16. The substrate processing apparatus of claim 11, wherein the plurality of gas holes include a plurality of edge gas holes,
wherein the plurality of edge gas holes are spaced apart from each other in a circumferential direction, and
wherein the first distance is greater than half a distance between two neighboring ones among the plurality of edge gas holes.

17. The substrate processing apparatus of claim 11, wherein the inner plate includes silicon (Si), and silicon (Si) on a surface of the inner plate has a crystallographic direction of <111>.

18. The substrate processing apparatus of claim 11, wherein a top surface of the central member, a top surface of the first coupling member, and a top surface of the outer ring body are on a same plane.

19. The substrate processing apparatus of claim 14, wherein the first angle is in a range of about 0.5° to about 6°, and the second angle is about 0°.

20. The substrate processing apparatus of claim 13, wherein a bottom surface of the second coupling member is at a same level as the bottom surface of the central member.
